(19) United States
(12) Patent Application Publication
(10) Pub. No.: US 2001/0054759 A1
(43) Pub. Date: Dec. 27, 2001

(54) Semiconductor device

(75) Inventor: Shinichi Nishiura, Fussa (JP)

Correspondence Address: KODA & ANDROLIA, Suite 3860, 2029 Century Park East, Los Angeles, CA, 90067-3024, US

(73) Assignee: KABUSHIKI KAISHA SHINKAWA

(21) Appl. No.: 09/871,870

(22) Filed: Jun. 1, 2001

(30) Foreign Application Priority Data
Jun. 2, 2000 (JP) 2000-165557

(51) Int. Cl. H01L 21/44; H01L 23/48; H01L 23/34; H01L 29/40

(52) U.S. Cl. 257/686; 438/109; 257/777; 438/617; 257/723; 257/776; 257/783

(57) ABSTRACT

A semiconductor device in which a plurality of semiconductor chips are stacked and fastened to a lead frame. First bonding points on the semiconductor chips and second bonding points on the leads of the lead frame are connected by trapezoidal loop shape wires which differ from each other in height, each of the wires comprising a neck portion which rises from the first bonding point, a trapezoidal portion which is continuous from the neck portion, and an inclined portion which is continuous from the trapezoidal portion, inclined toward the second bonding point and bonded to the second bonding point; and a bent portion is formed in at least a lowermost wire.

### BACKGROUND OF THE INVENTION

1. Field of the Invention

The present invention relates to a semiconductor device in which a plurality of semiconductor chips are mounted in a stacked fashion.

2. Prior Art

Recently, there has been a demand for a much higher capacity, higher functional performance and higher degree of integration in semiconductor devices. In order to meet this demand, some of the recent semiconductor device packages have a structure in which a plurality of semiconductor chips are mounted in a stacked or piled configuration, thus increasing the packaging density. In such packages with increased packaging density, it is necessary to increase the vertical spacing of the wires in order to prevent short-circuiting between wires that would be caused by, for instance, contact between adjacent wires and bending of the wires by molding at the time that the resin package is sealed.

In such packages, the portions of the wires located on the pad sides of the stacked semiconductor chips require certain spacing in the vertical direction. However, since the bonding points on the leads are on a same plain surface, the portions of the wires on the lead side of a lead frame are inevitably narrow in the vertical gap between wires.

Conventionally, therefore, the bonding points of adjacent leads on lead frames are further shifted from a second bonding position as disclosed in, for example, Japanese Patent Application Laid-Open (Kokai) Nos. H11-204720 and H11-87609.

In the above-described above prior art, since bonding is performed with the bonding points on the leads further shifted from the second bonding position, the size of the semiconductor device tends to become large. Furthermore, when the bonding distance is large, wire short-circuiting caused by sagging of the wires would likely to occur more often.

### SUMMARY OF THE INVENTION

Accordingly, the object of the present invention is to provide a semiconductor device which is reduced in size and in which short-circuiting of wires is prevented even when a semiconductor device has a large bonding distance.

The above object is accomplished by a unique structure for a semiconductor device of the present invention wherein: a plurality of semiconductor chips are stacked and fastened to a lead frame; first bonding points on the semiconductor chips and second bonding points on the leads of the lead frame are connected by a plurality of trapezoidal loop shape wires which differ from each other in the height, each of the wires comprising a neck portion which rises from the first bonding point, a trapezoidal portion which is continuous from the neck portion, and an inclined portion which is continuous from the trapezoidal portion, inclined toward the second bonding point and bonded to the second bonding point; and a bent portion is formed in at least the lowermost wire out of the.

The above object is accomplished by another unique structure for a semiconductor device of the present invention wherein: a plurality of semiconductor chips are stacked and fastened to a lead frame; and first bonding points on the semiconductor chips and second bonding points on the leads of the lead frame are connected by a plurality of trapezoidal loop shape wires which differ from each other in the height, each of the wires comprising a neck portion which rises from the first bonding point, a trapezoidal portion which is continuous from the neck portion at a first bent portion, and an inclined portion which is continuous from the trapezoidal portion at a second bent portion, inclined toward the second bonding point and bonded to the second bonding point, and wherein

a third bent portion is formed in the inclined portion of each one of the wires except for the uppermost wire, the inclined portion comprising: a trapezoidal-portion-side inclined portion which is between the third bent portion to the second bent portion, and a lead-side inclined portion which is between the third bent portion to the second bonding point, the trapezoidal-portion-side inclined portion having a larger angle of inclination than the lead side inclined portion;

the second bent portions of the respective wires are positioned so that the second bent portion of the lowest wire is furthest away from the second bonding point, and the second bent portion of each successively higher wire is positioned closer to the second bonding point, and

the angle of inclination of the trapezoidal-portion-side inclined portions of higher wires is larger than the angle of inclination of the trapezoidal-portion-side inclined portions of lower wires, and the angle of inclination of the lead-side inclined portions of higher wires is larger than the angle of inclination of the lead-side inclined portions of lower wires.

### BRIEF DESCRIPTION OF THE DRAWINGS

FIG. 1A is an explanatory front view of a first embodiment of the semiconductor device according to the present invention, and FIG. 1B is an explanatory top view thereof,

FIG. 2A is an explanatory front view of a second embodiment of the semiconductor device according to the present invention, and FIG. 2B is an explanatory top view thereof;

FIG. 3A is an explanatory front view of a third embodiment of the semiconductor device according to the present invention, and FIG. 3B is an explanatory top view thereof;

FIG. 4A is an explanatory front view of a fourth embodiment of the semiconductor device according to the present invention, and FIG. 4B is an explanatory top view thereof;

FIG. 5A is an explanatory front view of a fifth embodiment of the semiconductor device according to the present invention, and FIG. 5B is an explanatory top view thereof; and

FIG. 6A is an explanatory front view of a sixth embodiment of the semiconductor device according to the present invention, and FIG. 6B is an explanatory top view thereof.

### DETAILED DESCRIPTION OF THE INVENTION

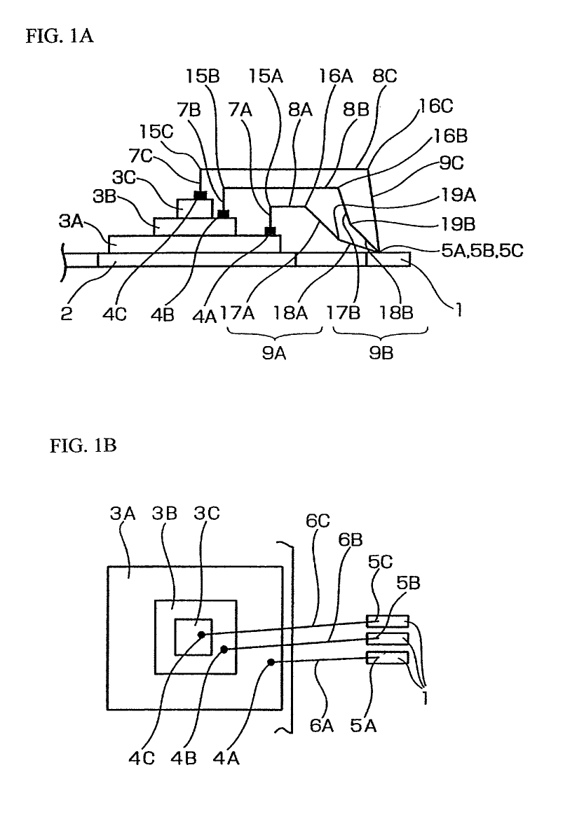

The first embodiment of the present invention will be described with reference to FIG. 1.

Three semiconductor chips 3A, 3B and 3C are mounted in a stacked fashion on a lead frame 2 which has leads 1. The lead frame 2 and the semiconductor chip 3A, the semiconductor chip 3A and semiconductor chip 3B, and the semiconductor chip 3B and semiconductor chip 3C are respectively fastened together by means of an adhesive sheet or adhesive agent (not shown). Wires 6A, 6B and 6C are respectively connected in the form of trapezoidal loops to, at one end thereof, first bonding points 4A, 4B and 4C on the electrodes of the semiconductor chips 3A, 3B and 3C and, at another end thereof, to second bonding points 5A, 5B and 5C on the leads 1. The wire 6A is the lowest in height, the wire 6C is the highest, and the wire 6B is in the middle. These connections are done by appropriate wire bonding apparatus (not shown).

As best seen from FIG. 1B, the second bonding points 5A, 5B and 5C are arranged on a (imaginary) straight line in the direction perpendicular to the respective leads 1.

The wires 6A, 6B and 6C comprise: neck portions 7A, 7B and 7C; trapezoidal portions 8A, 8B and 8C; and inclined portions 9A, 9B and 9C, respectively. The neck portions 7A, 7B and 7C which rise from the points where balls formed on the tip end of a wire that passes through the capillary (not shown) of a wire bonding apparatus (not shown) are bonded to the first bonding points 4A, 4B and 4C. The trapezoidal portions 8A, 8B and 8C are continuous from these neck portions 7A, 7B and 7C. The inclined portions 9A, 9B and 9C are continuous from the trapezoidal portions 8A, 8B and 8C and are inclined toward the second bonding points 5A, 5B and 5C and bonded to the second bonding points 5A, 5B and 5C.

At the continuing points of the neck portions 7A, 7B and 7C and the trapezoidal portions 8A, 8B and 8C are first bent portions 15A, 15B and 15C. Also, at the continuing points between the trapezoidal portions 8A, 8B and 8C and the inclined portions 9A, 9B and 9C are second bent portions 16A, 16B and 16C.

The inclined portions 9A and 9B of the wires 6A and 6B (i.e., the inclined portions of the wires other than the inclined portion 9C of the uppermost wire 6C) respectively comprise trapezoidal-portion-side inclined portions 17A and 17B and lead-side inclined portions 18A and 18B. The trapezoidal-portion-side inclined portions 17A and 17B are respectively positioned near the trapezoidal portions 8A and 8B, and the lead-side inclined portions 18A and 18B are respectively positioned near the leads 1. The trapezoidal-portion-side inclined portions 17A and 17B have, as best seen from FIG. 1A, a larger angle of inclination; and the lead-side inclined portions 18A and 18B have a smaller angle of inclination than the trapezoidal-portion-side inclined portions 17A and 17B.

Third bent portions 19A and 19B are formed at the connecting points between the trapezoidal-portion-side inclined portions 17A and 17B and the lead-side inclined portions 18A and 18B, respectively.

As seen from FIG. 1A, among the second bent portions 16A, 16B and 16C, the second bent portion 16A of the wire 6A is furthest away from the second bonding point 5A. The second bent portions 16B and 16C of the wires 6B and 6C, respectively, are successively shifted toward and located closer to the second bonding points 5B and 5C (the bent portion 16C is further toward the second bonding points than the bent portion 16B) and are successively higher (the bent portion 16C of the wire 6C is higher than the bent portion 16B of the wire 6B).

Among the angles of inclination of the trapezoidal-portion-side inclined portions 17A and 17B and inclined portion 9C, the angle of inclination of the trapezoidal-portion-side inclined portion 17A of the wire 6A is the smallest, and the trapezoidal-portion-side inclined portion 17B of the wire 6B and the inclined portion 9C of the wire 6C have successively larger angles of inclination.

Furthermore, among the angles of inclination of the lead-side inclined portions 18A and 18B and inclined portion 9C, the angle of inclination of the lead-side inclined portion 18A of the wire 6A is the smallest, and the lead-side inclined portion 18B of wire 6B and the inclined portion 9C of the wire 6C have successively larger angles of inclination.

Such wires 6A and 6B with a trapezoidal loop shape can be formed by the wire bonding method disclosed in, for instance, U.S. Pat. No. 5,961,029 that is owned by the applicant of the present application. Furthermore, the wire 6C with a trapezoidal loop shape can be also formed by the wire bonding method of the U.S. Pat. No. 5,961,029.

Thus, among the second bent portions 16A, 16B and 16C of the wires 6A, 6B and 6C, the lowest second bent portion 16A is most distant from the second bonding point 5A (or from the lead 1), and the upper second bent portions 16B and 16C are positioned successively closer to the second bonding points 5B and 5C (or from the leads 1).

Furthermore, the trapezoidal-portion-side inclined portions 17A and 17B and inclined portion 9C are formed with successively larger angles of inclination. In other words, the trapezoidal-portion-side inclined portion 17B of the wire 6B has a larger angle of inclination than the trapezoidal-portion-side inclined portion 17A of the wire 6A and the inclined portion 9C of the wire 6C has a larger angle of inclination than the trapezoidal-portion-side inclined portion 17B of the wire 6B.

On the other hand, the lead-side inclined portions 18A and 18B and inclined portion 9C are also formed with successively larger angles of inclination. In other words, the trapezoidal-portion-side inclined portion 18B of the wire 6B has a larger angle of inclination than the trapezoidal-portion-side inclined portion 18A of the wire 6A; and the inclined portion 9C of eh wire 6C has a larger angle of inclination than the trapezoidal-portion-side inclined portion 18B of the wire 6B.

Accordingly, even though the second bonding points 5A, 5B and 5C are arranged on a (imaginary) straight line, an increased and large spacing is secured for the lead-side inclined portions 18A and 18B and inclined portion 9C located on the second bonding points 5A, 5B and 5C sides. As a result, contact between the wires 6A, 6B and 6C and bending of the wires 6A, 6B and 6C that would be caused by molding during resin sealing, etc. are prevented.

In other words, the positions of the second bonding points 5A, 5B and 5C can be arranged on a straight line in the direction perpendicular to the respective leads 1 without causing any unfavorable situations to the wires. As a result, it is possible to reduce the size of semiconductor devices. Moreover, even if the bonding distance is long, short-circuiting of the wires can be prevented.

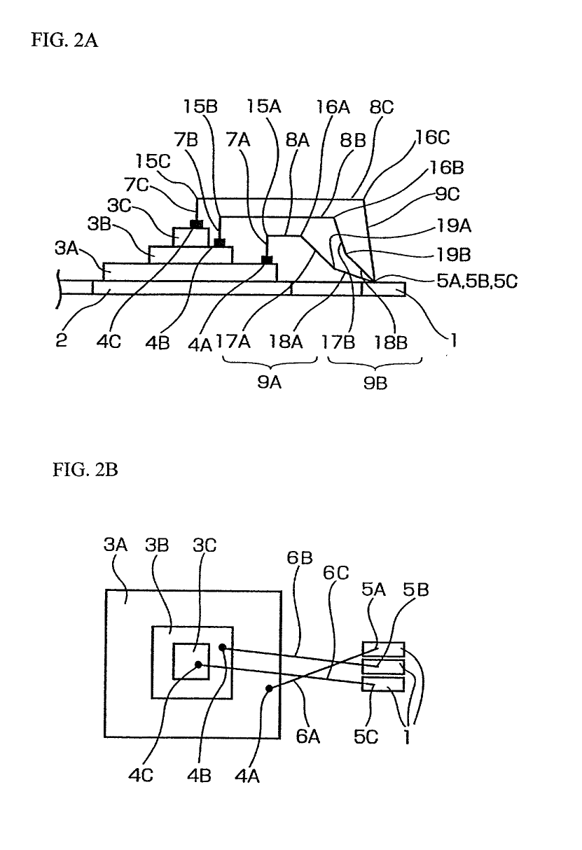

FIGS. 2 through 6 illustrate second through sixth embodiments of the present invention. The elements that are the same as or correspond to those in the above-described first embodiment will be labeled with the same reference numerals, and a detailed description of such elements will be omitted.

FIG. 2 illustrates a second embodiment of the present invention. In the semiconductor device of FIG. 1, the three wires 6A, 6B and 6C are provided without crossing each other when viewed from above. In the semiconductor device shown in FIG. 2, the wire 6A is provided so as to cross the wires 6B and 6C when viewed from above. In this case, as in the embodiment of FIG. 1, the second bent portions 16A, 16B and 16C of the respective wires 6A, 6B and 6C are arranged so that the lowest second bent portion 16A of the wire 6A is most distant from the second bonding point 5A. The upper second bent portions 16B and 16C of the wires 6B and 6C are positioned successively closer to the second bonding points 5B and 5C.

Furthermore, the trapezoidal-portion-side inclined portions 17A and 17B and inclined portion 9C are formed with successively larger angles of inclination, and the lead-side inclined portions 18A and 18B and inclined portion 9C are also formed with successively larger angles of inclination.

Accordingly, even though the second bonding points 5A, 5B and 5C are arranged on a straight line in the direction perpendicular to the respective leads 1, the spacing of the lead-side inclined portions 18A and 18B and inclined portion 9C located near the second bonding points 5A, 5B and 5C increases. Thus, the advantage same as that obtained in the first embodiment shown in FIG. 1 is obtained.

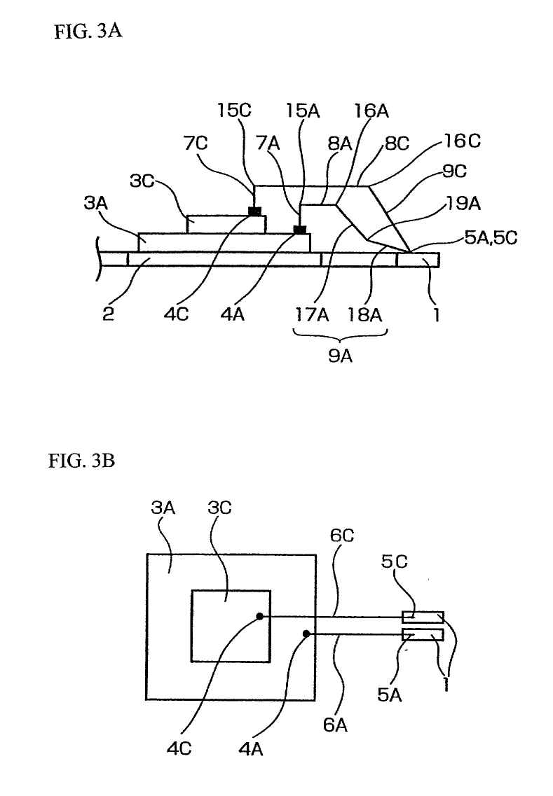

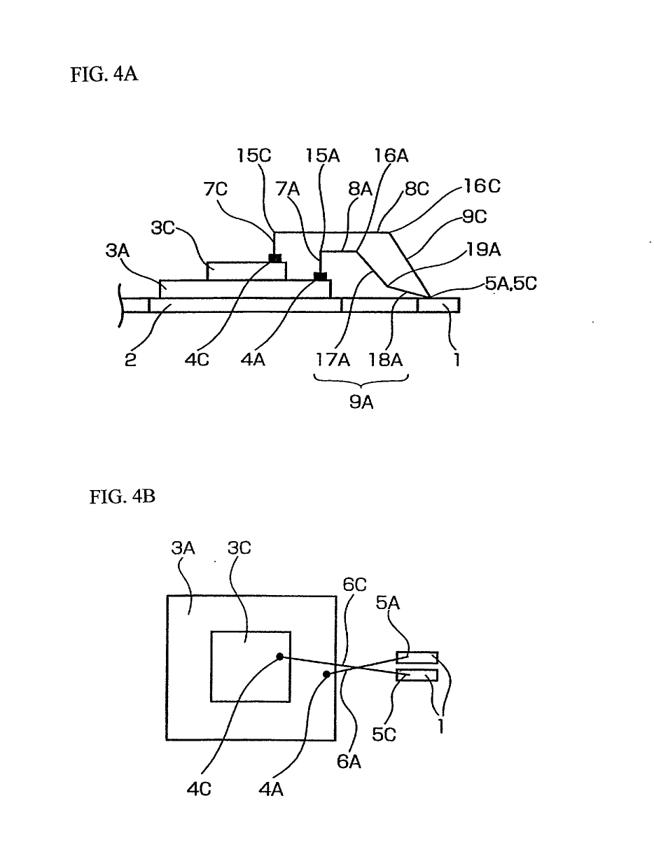

FIGS. 3 and 4 illustrate third and fourth embodiments of the present invention. FIGS. 1 and 2 illustrated a device in which three semiconductor chips 3A, 3B and 3C are mounted. FIGS. 3 and 4 illustrate a semiconductor device in which two semiconductor chips 3A and 3C are stacked.

In this case as well, the second bent portions 16A and 16C of the respective wires 6A and 6C are arranged so that the lower second bent portion 16A of the wire 6A is most distant from the second bonding point 5A and the upper second bent portion 16C of 6C is positioned closer to the second bonding point 5C. Furthermore, the trapezoidal-portion-side inclined portion 17A and inclined portion 9C are formed with successively larger angles of inclination, and the lead-side inclined portion 18A and inclined portion 9C are formed with successively larger angles of inclination. In other words, the inclined portion 9C of the wire 6C has a larger angle of inclination that of the trapezoidal-portion-side inclined portion 17A of the wire 6A, and the inclined portion 9C of the wire 6C has a larger angle of inclination than that of the lead-side inclined portion 18A.

Accordingly, with the second bonding points 5A and 5C arranged on a (imaginary) straight line in the direction perpendicular to the respective leads 1, an increased and larger spacing is secured between the lead-side inclined portion 18A and inclined portion 9C on the second bonding points 5A and 5C sides, and the same advantage as that obtained in the first embodiment shown in FIG. 1 is obtained.

As seen from the above, the number of semiconductor chips 3A, 3B, 3C . . . is not limited to three or two. The present invention can be applied for four or more stacked chips.

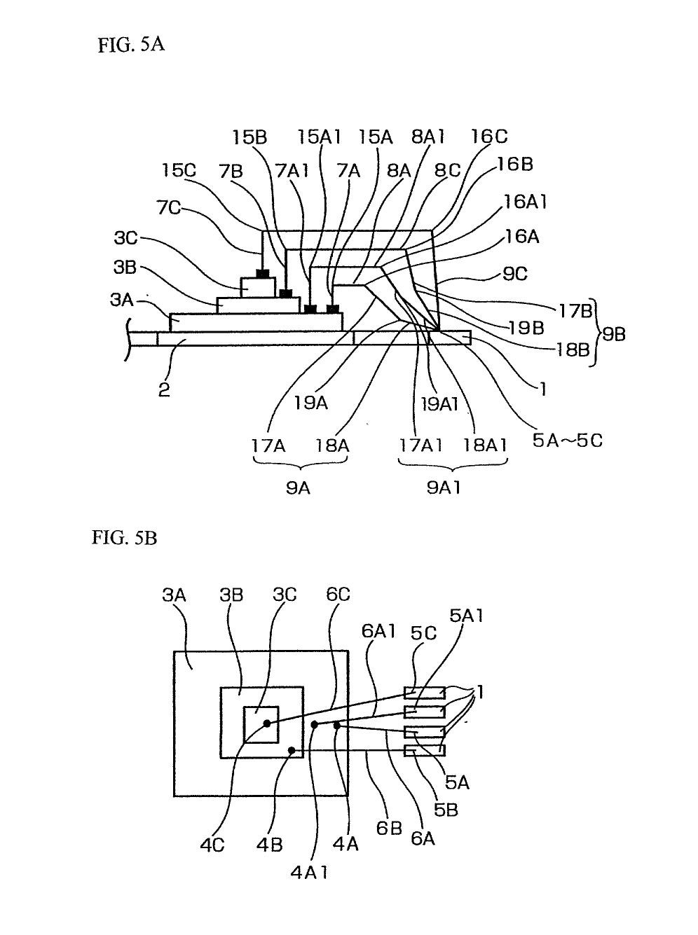

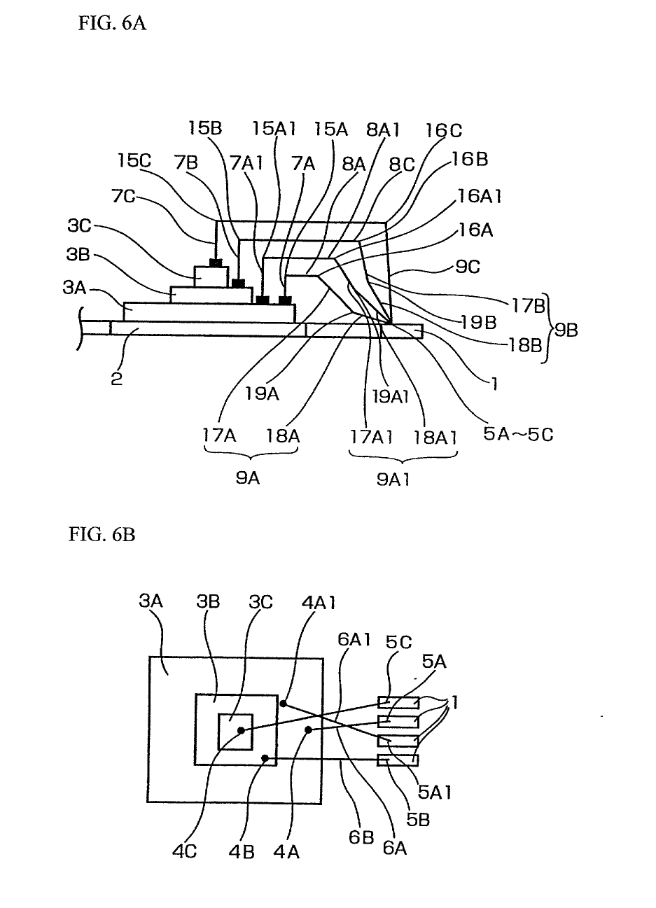

FIGS. 5 and 6 illustrate fifth and sixth embodiments of the present invention. In FIGS. 1 and 2, there is only a single bonding first bonding point 4A, 4B or 4C for each of the semiconductor chips 3A, 3B and 3C, and only a single lead 1 is provided for each of these first bonding points 4A, 4B and 4C. Generally, however, the first bonding points 4A, 4B and 4C of the respective semiconductor chips 3A, 3B and 3C have a plurality of bonding points disposed along the respective sides of each of the semiconductor chips 3A, 3B and 3C, and a lead 1 is provided for each of these first bonding points 4A, 4B and 4C. In each of FIGS. 5 and 6, the semiconductor device has the semiconductor chip 3A that has a first bonding point 4A1 in addition to the first bonding point 4A on one side.

In the semiconductor device shown in FIGS. 5 and 6 as well, as in the embodiment of FIG. 1, the second bent portions 16A, 16A1, 16B and 16C of the respective wires 6A, 6A1, 6B and 6C are arranged so that the lowest second bent portion 16A is most distant from the second bonding point 5A (or lead 1), and the upper second bent portions 16A1, 16B and 16C are positioned successively closer to the second bonding points 5A1, 5B and SC. Furthermore, the trapezoidal-portion-side inclined portions 17A, 17A1 and 17B and inclined portion 9C, and the lead-side inclined portions 18A, 18A1, 18B and inclined portion 9C, are formed with successively larger angles of inclination. Accordingly, even if the second bonding points 5A, 5A1, 5B and 5C are arranged on a (imaginary) straight line in the direction perpendicular to the respective leads 1 as best seen from FIGS. 5B and 6B, respectively, an increased and large spacing is secured for the lead-side inclined portions 18A, 18A1 and 18B and inclined portion 9C on the second bonding points 5A, 5A1, 5B and 5C side. Thus, the same advantage as in the first embodiment shown in FIG. 1 is obtained.

In FIGS. 5 and 6, the reference numeral 19A1 refers to the third bent portion of the wire 6A1.

In the above embodiments, except for the uppermost wire 6C, the inclined portions 9A, 9A1 and 9B of all of the wires 6A, 6A1 and 6B respectively have the third bent portions 19A, 19A1 and 19B. However, the same advantage can be obtained by way of forming a third bent portion 19A in at least the lowermost wire 6A.

As seen from the above, according to the present invention, a plurality of semiconductor chips are mounted and fastened to a lead frame; first bonding points on the semiconductor chips and the second bonding points on the leads of the lead frame are connected by trapezoidal loop shape wires, each of the wires comprises a neck portion which rises from the first bonding point, a trapezoidal portion which is continuous from this neck portion, and an inclined portion which is continuous from the trapezoidal portion, inclined toward the second bonding point, and bonded to the second bonding point; and the inclined portion of the wires (at least the lowermost wire) other than the uppermost wire is formed with a bent portion. Accordingly, the size of semiconductor device can be reduced, and short-circuiting of the wires can be prevented even if the bonding distance is long.

1. A semiconductor device wherein:
a plurality of semiconductor chips are stacked and fastened to a lead frame, and
first bonding points on said plurality of semiconductor chips and second bonding points on leads of said lead frame are connected by trapezoidal loop shape wires which differ from each other in height, each of said wires comprising a neck portion which rises from said first bonding point, a trapezoidal portion which is continuous from said neck portion at a first bent portion, and an inclined portion which is continuous from said trapezoidal portion at a second bent portion, inclined toward said second bonding point and bonded to said second bonding point, and wherein
a bent portion is formed in said inclined portion of at least a lowermost wire.

2. A semiconductor device wherein:
(a) a plurality of semiconductor chips are stacked and fastened to a lead frame;
(b) first bonding points on said plurality of semiconductor chips and second bonding points on leads of said lead frame are connected by trapezoidal loop shape wires which differ from each other in height, each of said wires comprising a neck portion which rises from said first bonding point, a trapezoidal portion which is continuous from said neck portion at a first bent portion, and an inclined portion which is continuous from said trapezoidal portion at a second bent portion, inclined toward said second bonding point and bonded to said second bonding point, and wherein
(c) a third bent portion is formed in said inclined portion of each one of said wires except for an uppermost wire, so that said inclined portion comprises:
(i) a trapezoidal-portion-side inclined portion which is between said third bent portion to said second bent portion, and
(ii) a lead-side inclined portion which is between said third bent portion and said second bonding point,
(iii) said trapezoidal-portion-side inclined portion having a larger angle of inclination than the lead side inclined portion;
(d) said second bent portions of said respective wires are positioned so that a second bent portion of a lowest wire is furthest away from said second bonding point, and a second bent portion of each successively higher wire is positioned closer to said second bonding point, and
(e) an angle of inclination of said trapezoidal-portion-side inclined portions of higher wires is larger than an angle of inclination of said trapezoidal-portion-side inclined portions of lower wires, and an angle of inclination of said lead-side inclined portions of higher wires is larger than an angle of inclination of said lead-side inclined portions of lower wires.
